(19) United States
(12) Patent Application Publication
(10) Pub. No.: US 2026/0113893 A1
(43) Pub. Date: Apr. 23, 2026

(54) COOLING DISTRIBUTION UNIT WITH FILTER AND FLUSH VALVE

(71) Applicant: LTI Holdings Inc., Pleasanton, CA (US)

(72) Inventors: Steven J. Medeiros, Loudon, NH (US); Jeffrey A. Henning, Exeter, NH (US)

(21) Appl. No.: 19/359,924

(22) Filed: Oct. 16, 2025

Related U.S. Application Data
(60) Provisional application No. 63/708,575, filed on Oct. 17, 2024.

(51) Int. Cl. H05K 7/20

(52) U.S. Cl. CPC H05K 7/20763

(57) ABSTRACT

A cooling distribution unit includes a heat exchanger, a primary closed loop configured to circulate a first fluid through the heat exchanger, and a secondary closed loop configured to circulate a second fluid through the heat exchanger. The second fluid is configured to be cooled by the first fluid. The primary closed loop includes a first strainer having a first filter configured to collect debris from the first fluid and a first flush valve configured to selectively remove the debris from the first filter. The secondary closed loop includes a second strainer including a second filter configured to collect debris from the second fluid and a second flush valve configured to selectively remove the debris from the second filter. The third strainer includes a third filter configured to collect debris from the second fluid and a third flush valve configured to selectively remove the debris from the third filter.

### CROSS-REFERENCE TO RELATED APPLICATIONS

This application claims priority to U.S. Provisional Application No. 63/708,575, filed Oct. 17, 2024, the entire contents of which are incorporated herein by reference.

### FIELD

The present disclosure generally relates to cooling distribution units for directing heat away from electrical components.

### BACKGROUND

Cooling distribution units (commonly referred to as CDU's) are often utilized in data centers to remove heat from computer components (e.g., servers and server racks). Cooling distribution units may include, for example, both in-row units and in-rack units. In-row units remove heat from an entire row of server racks or other sets of electrical components, while in-rack units typically remove heat from a single rack or set of electrical components.

### SUMMARY

In accordance with one example, a cooling distribution unit includes a heat exchanger, a primary closed loop configured to circulate a first fluid through the heat exchanger, and a secondary closed loop configured to circulate a second fluid through the heat exchanger. The second fluid is configured to be cooled by the first fluid. The primary closed loop includes a first strainer having a first filter and a first flush valve. The first filter is configured to collect debris from the first fluid. The first flush valve is configured to selectively remove the debris from the first filter. The secondary closed loop includes a second strainer and a third strainer. The second strainer includes a second filter and a second flush valve. The second filter is configured to collect debris from the second fluid. The second flush valve is configured to selectively remove the debris from the second filter. The third strainer includes a third filter and a third flush valve. The third filter is configured to collect debris from the second fluid. The third flush valve is configured to selectively remove the debris from the third filter.

The details of one or more aspects of the disclosure are set forth in the accompanying drawings and the description below. Other features, objects, and advantages of the techniques described in this disclosure will be apparent from the description and drawings, and from the claims.

### BRIEF DESCRIPTION OF THE DRAWINGS

FIG. 1 is a schematic view of a cooling distribution unit in accordance with one example.

FIG. 2 is a perspective view of the cooling distribution unit of FIG. 1.

FIG. 3 is another perspective view of the cooling distribution unit of FIG. 1.

FIG. 4 is another perspective view of the cooling distribution unit of FIG. 1

FIG. 5 is a side view of a portion of the cooling distribution unit of FIG. 1.

FIG. 6 is a schematic view of a portion of a primary closed loop of the cooling distribution unit of FIG. 1.

FIG. 7 is a schematic view of a portion of a secondary closed loop of the cooling distribution unit of FIG. 1.

### DETAILED DESCRIPTION

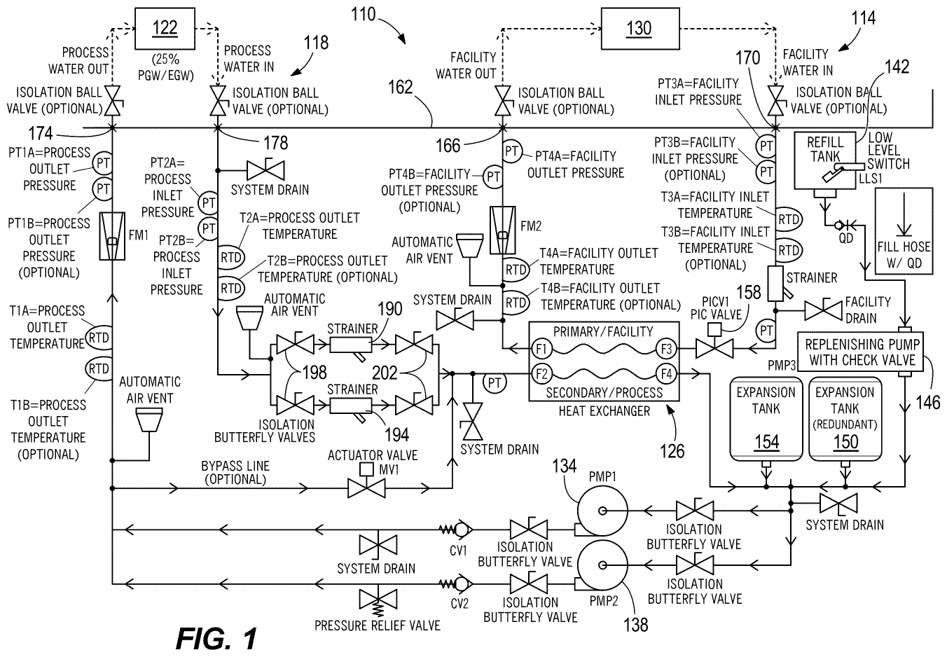

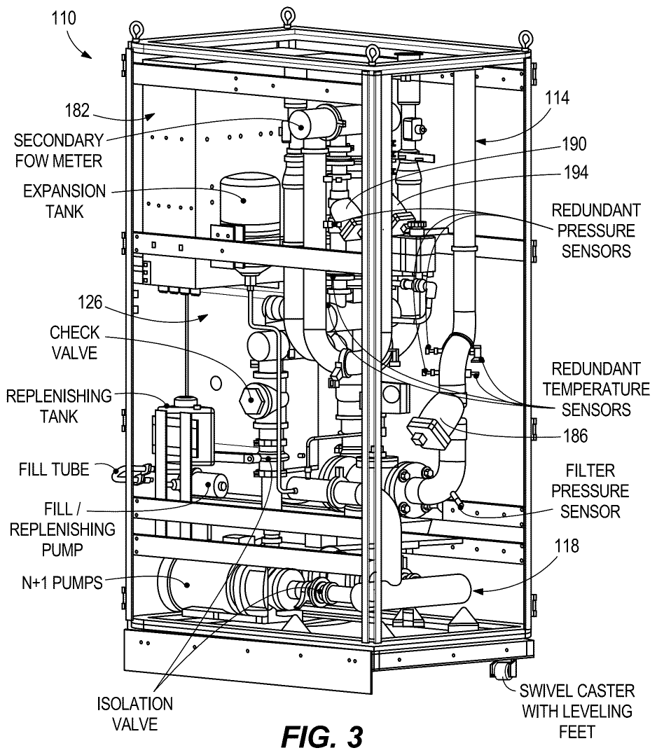

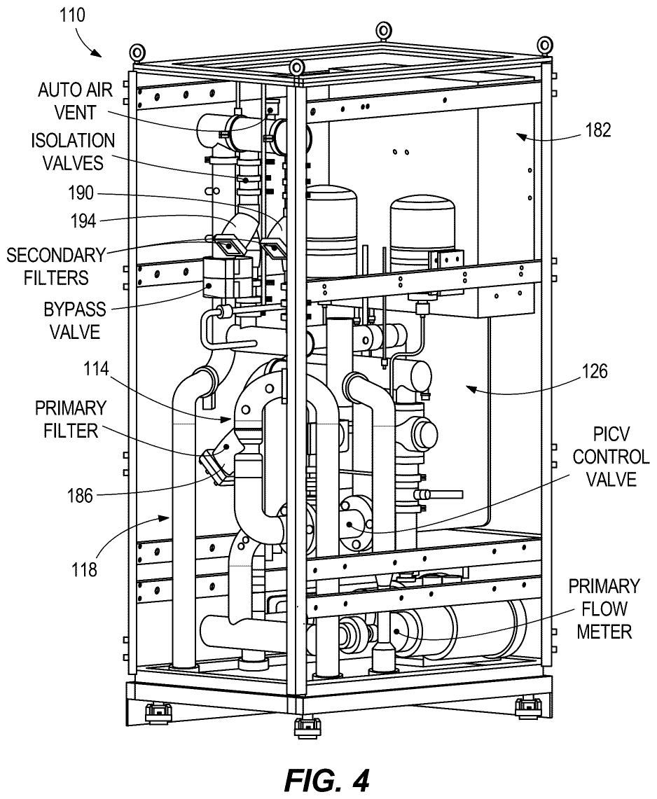

FIGS. 1-4 illustrate an example of a cooling distribution unit 110. The cooling distribution unit 110 may be used in any of a variety of settings, including for example in a server, data center, medical, semiconductor, and/or industrial application. The illustrated cooling distribution unit 110 is an in-row unit, although any of the concepts described herein related to the cooling distribution unit 110 may alternatively be used with an in-rack unit, or with any other type of cooling distribution unit.

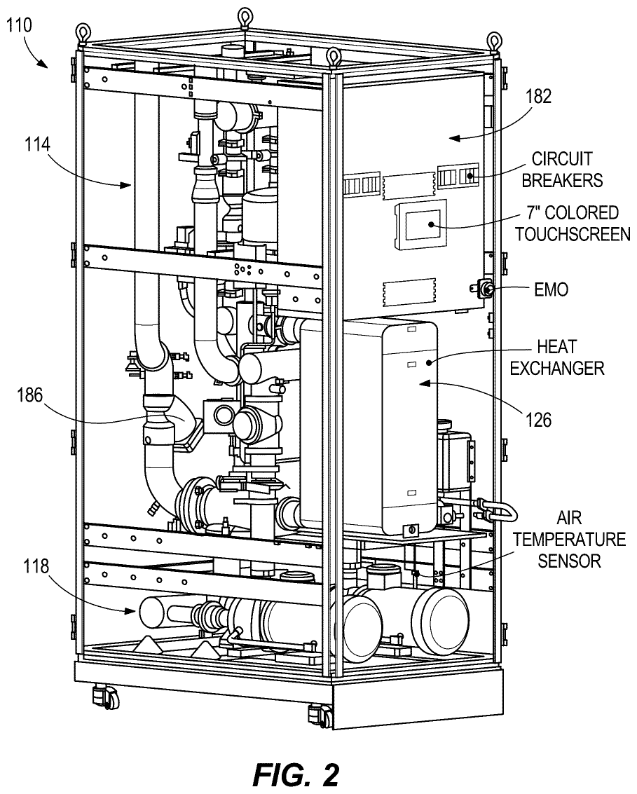

With reference to FIG. 1, the cooling distribution unit 110 generally includes a primary closed loop 114 and a secondary closed loop 118. The primary closed loop 114 circulates a first fluid (e.g., facility water located and/or otherwise supplied at a data server center). The secondary closed loop 118 circulates a second fluid (e.g., a process water solution that includes 25% propylene glycol and 75% water). Other examples include different first and second fluids within either of the primary closed loop 114 or the secondary closed loop 118. As illustrated in FIGS. 2-4, the primary closed loop 114 includes piping (e.g., stainless steel piping) through which the first fluid circulates. The secondary closed loop 118 similarly includes piping (e.g., stainless steel piping) through which the second fluid circulates. Other examples include other types of piping, including piping made of other materials, or having other shapes and configurations than that illustrated.

In some examples, the first fluid may be composed of or include water or propylene glycol-water solutions having a 50% maximum concentration. In other words, the concentration of the glycol-water solution may have a maximum concentration of 10 mg/L. The second fluid may be composed of or include water or a premixed solution of uninhibited ethylene-glycol or propylene-glycol and water. The first fluid and the second fluid may have a largest particle size of less than 200 microns. Other examples may include other materials and/or compositions of materials and/or particle sizes for the first fluid and/or the second fluid.

With continued reference to FIG. 1, the secondary closed loop 118 circulates the second fluid through and/or across one or more electrical components 122, to pick up heat from the electrical components 122. The electrical components 122 may include, for example, computer chips or other heated electrical components in one or more servers or server racks. In some examples, cold plates or other thermal devices may be positioned over the computer chips, and the piping of the secondary closed loop 118 may pass through the cold plates or other thermal devices to pick up the heat from the electrical components 122. Once the second fluid in the secondary closed loop 118 has been heated by the electrical components 122, the heated second fluid is directed to a heat exchanger 126.

With continued reference to FIG. 1, each of the primary closed loop 114 and the secondary closed loop 118 extends through the heat exchanger 126. In the illustrated example, the heat exchanger 126 is a liquid-to-liquid heat exchanger. The primary closed loop 114 directs the first fluid in a first direction (e.g., to the left as viewed in FIG. 1) through the heat exchanger 126, and the secondary closed loop 118 directs the second fluid in a second direction (e.g., to the right as viewed in FIG. 1) through the heat exchanger 126. In the illustrated example, the first direction is parallel to, and opposite, the first direction. In other examples the first fluid and the second fluid may be directed in the same direction, or in a transverse direction, or the first and second fluids may be moved in more than one direction in the heat exchanger 126.

Within the heat exchanger 126, heat is exchanged between the second fluid and the first fluid. Accordingly, at least a portion of the heat picked up from the electrical components 122 is transferred from the second fluid to the first fluid within the heat exchanger 126. In some examples, the piping of the primary closed loop 114 does not contact the piping of the secondary closed loop 118 within the heat exchanger 126, and the heat is exchanged through an intermediary material (e.g., through a thermally conductive material). Other examples may include various other types or numbers or arrangements of heat exchangers 126 than that illustrated.

With continued reference to FIG. 1, the primary closed loop 114 directs the first fluid (after having been heated in the heat exchanger 126) away from the heat exchanger 126, and to a cooling structure 130. The cooling structure 130 may be located for example within a data server center. The cooling structure 130 may be any of a variety of different structures, including a cooling tower or other thermal device that sheds or otherwise removes heat from the first fluid. In some examples, the cooling structure 130 may include a cold plate, fins, and/or other structures that remove heat, and/or may use a fan or fans to facilitate removal of heat from the first fluid.

As illustrated in FIG. 1, once the heat has been removed from the first fluid at the cooling structure 130, the first fluid is then circulated back toward the heat exchanger 126. Similarly, once the heat has been removed from the second fluid at the heat exchanger 126, the second fluid is circulated back toward the electrical components 122. This circulation through each of the primary closed loop 114 and the secondary closed loop 118 may continue (e.g., for as long as the electrical components 122 are generating heat), such that heat is continuously picked up from the electrical components and delivered to the heat exchanger 126, where the heat is then transferred to the first fluid and the primary closed loop 114, and eventually discarded at the cooling structure 130.

With continued reference to FIG. 1, each of the primary closed loop 114 and the secondary closed loop 118 may include one or more pumps to pump the first fluid and the second fluid through the piping. In the illustrated example, the primary closed loop 114 includes one or more pumps (not illustrated) located within the data server center (e.g., at the location of the cooling structure 130, or elsewhere within the data server center, to pump the first fluid (e.g., facility water) through the primary closed loop 114. The secondary closed loop 118 includes both a first pump 134 and a second pump 138. The first and second pumps 134, 138 are redundant pumps, positioned along parallel lines within the closed loop, such that if one of the pumps fails, the other may continue to operate the overall flow of the second fluid within the secondary closed loop 118. The first pump 134 and the second pump 138 may be any type of pump that is capable of pumping the second fluid. In some examples, the first pump 134 and the second pump 138 are identical pumps, having a same size and/or rating. In some examples, one or more of the first pump 134 or the second pump 138 is a centrifugal pump. Other examples include other types of pumps, and also numbers of pumps. For example, secondary closed loop 118 may in some examples include only a single pump, or may include more than two pumps. Overall, the first pump 134 and/or the second pump 138 may generate a flow rate of for example between 25 gallons per minute (GPM) and 200 GPM (e.g., 25 GPM, 50 GPM, 100 GPM, 125 GPM, 140 GPM, 160 GPM, or other values and ranges of values).

With continued reference to FIG. 1, in some examples the secondary closed loop 118 includes a refill tank 142 and a replenishing pump 146, for adding additional second fluid into the secondary closed loop 118. Additionally, in some examples the secondary closed loop 118 includes at least one expansion tank, for controlling an overall pressure and flow of the second fluid in the secondary closed loop 118. In the illustrated example, the secondary closed loop 118 includes a first expansion tank 150 and a second (e.g., redundant) expansion tank 154. Other examples may include just a single expansion tank, or more than two expansion tanks.

Additionally, both the primary closed loop 114 and the secondary closed loop 118 may include one or more valves (e.g., pressure control valves, check valves, pressure independent control valves, etc.) that operate to control the overall pressure and/or flow of fluid through the cooling distribution unit 110. In the illustrated example, the primary closed loop 114 includes a pressure independent control valve 158.

With continued reference to FIG. 1, in the illustrated example, the cooling distribution unit 110 includes a housing 162 (e.g., an outer housing). The housing 162 may include a steel frame (e.g., with interconnected vertical and/or horizontal frame members), or may be another type of frame, or be formed from different materials. In some examples, the housing 162 may include one or more doors (e.g., pivotally coupled or otherwise coupled to the frame). Other examples may include various other types, sizes, and/or shapes of housing 162 than that illustrated. In the illustrated example, the housing 162 includes a first outlet 166 where the primary closed loop 114 exits, and the first fluid is sent to the cooling structure 130. The housing 162 also includes a first inlet 170, wherein the primary closed loop 114 enters, and wherein the first fluid is then directed to the heat exchanger 126 (e.g., located within the housing 162). The housing 162 also includes a second outlet 174, where the secondary closed loop 118 exits and the second fluid is sent to the electrical components 122, and a second inlet 178, where the second fluid enters and is then directed to the heat exchanger 126.

With continued reference to FIG. 1, in some examples, the cooling distribution unit 110 additionally includes one or more sensors that measure pressure, temperature, or other aspects of the system. In the illustrated example, the cooling distribution unit 110 includes a plurality of pressure and temperature sensors (labeled as “PT” and “RTD” in FIG. 1) that are positioned generally at the first outlet 166, the first inlet 170, the second outlet 174, and the second inlet 178. As illustrated in FIG. 1, the cooling distribution unit 110 may include redundant pressure and temperature sensors (e.g., in the event one or more of the sensors fails or provide inaccurate readings).

In some examples, these sensors are coupled (e.g., wired or wirelessly) to a controller 182 (FIGS. 2-4) or other device that receives signals regarding the pressure and temperature of the first fluid and the second fluid. In the illustrated example, the controller 182 is located on and/or within the housing 162, and may include a user interface (e.g., graphical user interface, such as a color touchscreen). In some examples, the controller 182 is located remotely from the housing 162. In some examples, the controller 182 may be used to monitor pressure, monitor temperature, and/or control a flow and pressure differential of the second fluid.

With reference to FIG. 1, each of the primary closed loop 114 and the secondary closed loop 118 may include one or more strainer assemblies to collect any debris or particulates from the piping. In the illustrated example, the primary closed loop 114 includes a first strainer assembly 186. The first strainer assembly 186 (also referred to as a first strainer 186) is located upstream of the heat exchanger 126. Stated another way, the first fluid is configured to flow through the first strainer assembly 186 before flowing into the heat exchanger 126. More specifically, the illustrated first strainer assembly 186 is positioned between the pressure independent control valve 158 and the first inlet 170. In other examples, the first strainer assembly 186 can be positioned elsewhere in the primary closed loop 114. The secondary closed loop 118 includes both a second strainer assembly 190 (also referred to as a second strainer 190) and a third strainer assembly 194 (also referred to as a third strainer 194). The second and third strainer assemblies 190, 194 are redundant strainers, positioned along parallel lines within the closed loop, such that if one of the second or third strainer assemblies 190, 194 fails, the other may continue to filter out the debris within the second fluid within the secondary closed loop 118. The redundant strainers also allow for one of the second or third strainer assemblies 190, 194 to be isolated from the rest of the secondary closed loop 118 and flushed or repaired, which is described in further detail below. The second and third strainer assemblies 190, 194 are positioned upstream of the heat exchanger 126. Stated another way, the second fluid is configured to flow through at least one of the second and third strainer assemblies 190, 194 before flowing into the heat exchanger 126. In other examples, the second and third strainer assemblies 190, 194 can be positioned elsewhere in the secondary closed loop 118. In the illustrated example, the first, second, and third strainer assemblies 186, 190, 194 are Y-strainers, although other examples include other types of strainers.

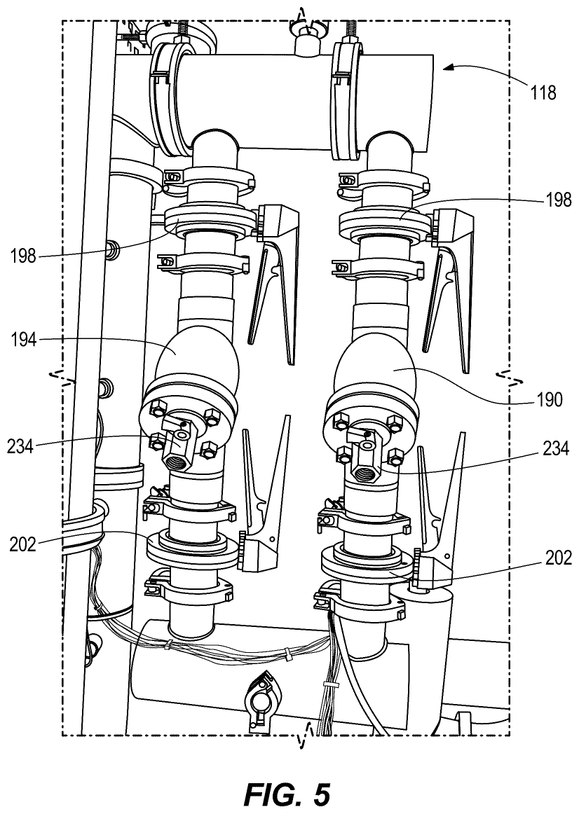

With reference to FIGS. 1 and 5, each of the second and third strainer assemblies 190, 194 is positioned between a pair of valves (e.g., butterfly valves, gate valves, ball valves, etc.). Each pair of valves includes an upstream valve 198 (also referred to as a first valve 198) and a downstream valve 202 (also referred to as a second valve 202). The second fluid is configured to flow through the associated upstream valve 198 before flowing into the respective second or third strainer assembly 190, 194, and the second fluid flows through the associated downstream valve 202 after flowing through the respective second or third strainer assembly 190, 194. Each upstream and downstream valve 198, 202 is adjustable between an opened position and a closed position to alter the flow within the secondary closed loop 118. For example, both the upstream valve 198 and the downstream valve 202 (e.g., located adjacent the second strainer assembly 190) can be closed to fluidly isolate the second strainer assembly 190 from the rest of the secondary closed loop 118.

As another example, the downstream valve 202 (e.g., located adjacent the second strainer assembly 190) can be closed first, and the upstream valve 198 can be subsequently closed. This will result in some of the second fluid trapped between the upstream and downstream valves 202. Some or all of this trapped second fluid can be used to, for example, flush the second strainer assembly 190, which is described in further detail below. It should be appreciated that the above-described examples similarly apply to the third strainer assembly 194 and the associated upstream and downstream valves 198, 202 associated with the third strainer assembly 194.

The upstream and downstream valves 198, 202 can be manually opened and closed by a user. Alternatively, the upstream and downstream valves 198, 202 can be connected to the controller 182 and opened and closed by the controller 182. In some examples, the upstream and downstream valves 198, 202 are identical.

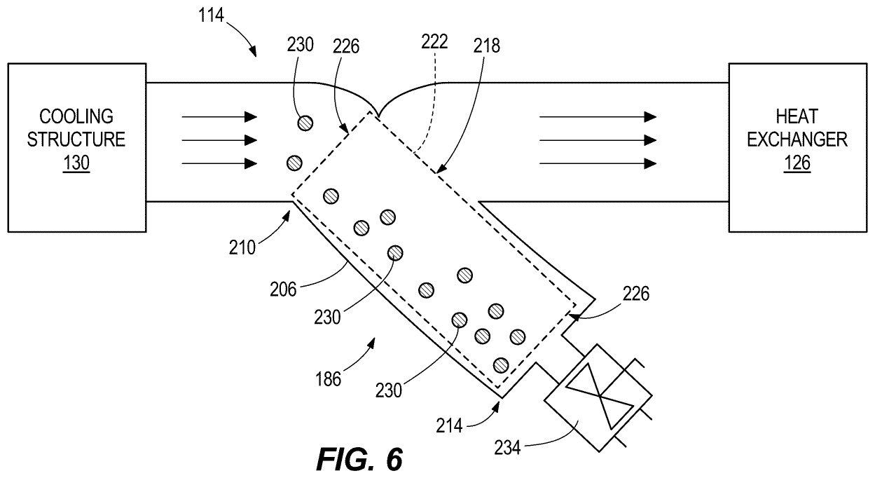

With reference to FIG. 6, the first strainer assembly 186 is illustrated in greater detail. The first strainer assembly 186 includes a strainer housing 206. The strainer housing 206 extends obliquely from the tubing of the primary closed loop 114. The strainer housing 206 includes a first end 210 adjacent the tubing of the primary closed loop 114 and a second end 214 opposite the first end 210 and spaced apart from the tubing. A first filter 218 (e.g., a first strainer basket or other filter) is received within the strainer housing 206. In some examples, the first filter 218 includes a cylindrical wall 222 with a pair of opposite openings 226. The cylindrical wall 222 is configured to filter the first fluid. The cylindrical wall 222 includes pores that allow the first fluid to pass through and inhibit or prevents debris 230 from passing through. In the illustrated example, the first filter is a 500 micron filter. In other examples, the first filter 218 can be a 200 micron filter, a 100 micron filter, a 50 micron filter, a 20 micron filter, or any suitable filter to allow the first fluid to pass through while inhibiting or preventing the debris 230 from passing through. The openings 226 may be oriented such that one opening 226 is adjacent the first end 210 and the other opening 226 is adjacent the second end 214. In some examples, the first filter 218 is reversible, such that either opening 226 of the first filter 218 can be adjacent either the first or second end 210, 214 of the strainer housing 206. Other examples may include other types of first filters, or different arrangements of components for the first filter 218.

During operation, the first fluid (and any debris 230) flows through the piping of the primary closed loop 114 in a direction from the cooling structure 130 toward the first strainer assembly 186. The first fluid flows into the opening 226 of the first filter 218 adjacent the first end 210. The first fluid then flows through the cylindrical wall 222 in a direction from the first strainer assembly 186 and toward the heat exchanger 126. The debris 230 is unable to pass through the cylindrical wall 222, so the debris 230 collects within the first filter 218. As such, the first fluid flowing past the first strainer assembly 186 is free of the debris 230 or substantially free of the debris 230. The debris 230 may settle in the first filter 218 adjacent the second end 214 of the strainer housing 206.

With continued reference to FIG. 6, the first strainer assembly 186 also includes a flush valve 234 (e.g., butterfly valve, gate valve, ball valve, etc.) to selectively remove the debris 230 from the first strainer assembly 186 without having to disassemble the first strainer assembly 186. The flush valve 234 is coupled to the second end 214 of the strainer housing 206. The flush valve 234 is adjustable between an opened position and a closed position. During operation, the first fluid is flowing through the primary closed loop 114, and the flush valve 234 is in the closed position. If a user wants to remove the build-up of debris 230 from the first strainer assembly 186, the user can optionally shut off the pump(s) that circulate the first fluid through the primary closed loop 114. This will reduce or eliminate the flow of the first fluid through the primary closed loop 114, so that once the flush valve 234 is opened, the first fluid will not spray out of the flush valve 234. The user does not need to shut off the first and/or second pumps 134, 138 that flow the second liquid through the secondary closed loop 118. As such, the secondary closed loop 118 can continue to operate to cool off the electrical components 122 while the flow of the first fluid through the primary closed loop 114 has stopped. With the flow of the first fluid stopped, a user can then move the flush valve 234 to the opened position. Once in the opened position, the debris 230 can be removed from inside the first filter 218. If the user did not shut off the pumps (or optionally decreased the speed of the pumps), the first fluid will also flow out of the flush valve 234. The flow of first fluid through the flush valve 234 can assist in removing the debris 230 from the first strainer assembly 186. Once the debris 230 is removed, the user can move the flush valve 234 to the closed position and turn on the pumps to resume circulating the first fluid throughout the primary closed loop 114 (in examples in which the pumps were turned off).

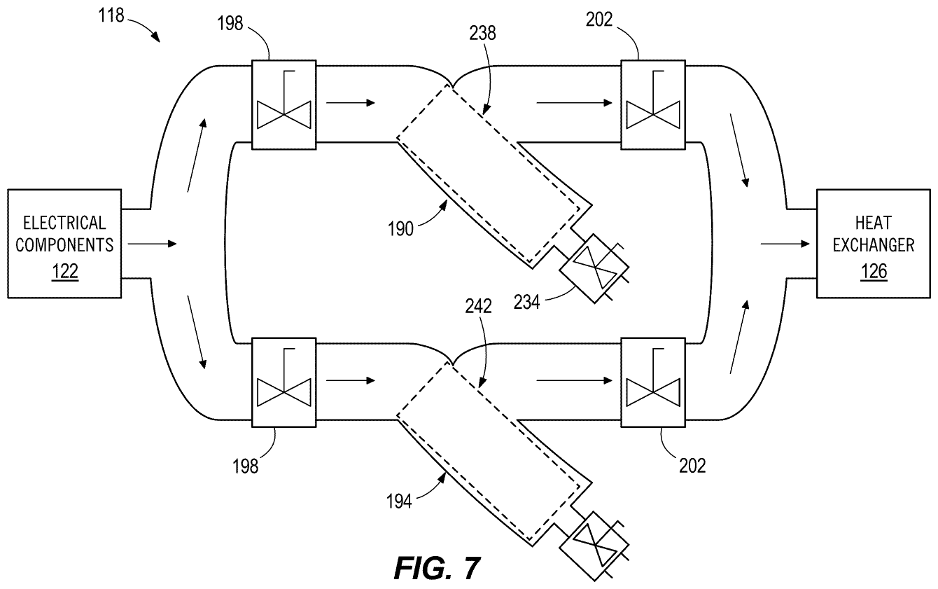

FIG. 7 illustrates the second and third strainer assemblies 190, 194 in greater detail. The second and third strainer assemblies 190, 194 may each include many of the same components as the first strainer assembly 186. Similar components of the second and third strainer assemblies 190, 194 are labeled the same as like components in the first strainer assembly 186. For brevity, only differences between the second and third strainer assemblies 190, 194 and the first strainer assembly 186 are described herein. It should be appreciated that the second strainer assembly 190 and/or the third strainer assembly 194 can include any component or feature described with reference to the first strainer assembly 186.

With continued reference to FIG. 7, in the illustrated example the second strainer assembly 190 includes a second filter 238 and the third strainer assembly 194 includes a third filter 242. The second and third filters 238, 242 can be identical, or may be different. In the illustrated example, the second and third filters 238, 242 are 50 micron filters. In other examples, the second and third filters 238, 242 can be 500 micron filters, 200 micron filters, 100 micron filters, 20 micron filters, or any suitable filters to allow the second fluid to pass through while preventing the debris 230 from passing through. Other examples may include other types of second and third filters, or different arrangements of components for the second and third filters 238, 242.

During operation, the second fluid flows through the secondary closed loop 118, and the flush valves 234 of the second and third strainer assemblies 190, 194 are in the closed position. If a user wants to remove the build-up of debris 230 from either the second strainer assembly 190 or the third strainer assembly 194, the first and/or second pumps 134, 138 do not have to be shut off. Rather, the first and/or second pumps 134, 138 can continue to operate and circulate the second fluid through the secondary closed loop 118 to cool the electrical components 122. The first and/or second pumps 134, 138 can remain on because the second and third strainer assemblies 190, 194 are in parallel. As such, while the user is removing the debris 230 from one of the second or third strainer assemblies 190, 194, the other of the second or third strainer assemblies 190, 194 can continue to filter the second fluid flowing therethrough.

Accordingly, if a user wants to remove the build up of debris 230 from the second strainer assembly 190, the user can close the upstream and downstream valves 198, 202 that are on either side of the second strainer assembly 190. This will stop the flow of the second fluid through the second strainer assembly 190, so that once the associated flush valve 234 is opened, the second fluid will not uncontrollably spray out of the flush valve 234. Rather, the user can optionally close the downstream valve 202 first and then subsequently close the upstream valve 198. At this point, some of the second fluid is trapped between the upstream and downstream valves 198, 202. The user can then move the flush valve 234 coupled to the strainer housing 206 of the second strainer assembly 190 to the opened position.

Once in the opened position, some or all of the second fluid trapped between the upstream and downstream valves 198, 202 will flow out of the flush valve 234 and can assist in removing the debris 230 from inside the second filter 238. In other examples, the user can close the upstream valve 198 first and then wait for all or a majority of the second fluid to exit the area between the upstream valve 198 and the downstream valve 202. The user can then optionally close the downstream valve 202. The user can then move the flush valve 234 coupled to the strainer housing 206 of the second strainer assembly 190 to the opened position. Once in the opened position, the debris 230 can be removed from inside the second filter 238 (e.g., via gravity, via a tool inserted through the flush valve 234, etc.). Once the debris 230 is removed, the user can move the flush valve 234 to the closed position. The upstream and downstream valves 198, 202 that are on either side of the second strainer assembly 190 can then be re-opened to resume the flow of the second fluid through the second strainer assembly 190. It should be appreciated that the process for removing the debris 230 from the third strainer assembly 194 is the same as described with reference to the second strainer assembly 190.

In some examples, the first strainer assembly 186 can be replaced with a pair of redundant strainers. The pair of redundant strainers can have the same function and features as the redundant second and third strainer assemblies 190, 194. The primary closed loop 114 can also include an upstream valve 198 and a downstream valve 202 on either side of each redundant strainer. As such, it should be appreciated that the process for removing the debris 230 from the redundant strainers in the primary closed loop 114 can be the same as described with reference to the redundant second and third strainer assemblies 190, 194.

In the illustrated example, the cooling distribution unit 110 has an overall dimension of 31.5″ by 47.4″ by 84.5″, and an overall weight of approximately 1400 pounds. Other examples may include different sizes and weights, including sizes smaller and larger than that illustrated, and weights smaller or greater than that illustrated. Additionally, in the illustrated example, the cooling distribution unit 110 may provide a cooling capacity of 550 kW (at 4° C. approach temperature difference) and 1100 kW (at 8° C. approach temperature difference). Other examples may include other values and ranges of values of cooling capacity, including a cooling capacity smaller or greater than that illustrated.

Although various aspects and examples have been described in detail with reference to certain examples illustrated in the drawings, variations and modifications exist within the scope and spirit of one or more independent aspects described and illustrated.

What is claimed is:

1. A cooling distribution unit comprising:
a heat exchanger;
a primary closed loop configured to circulate a first fluid through the heat exchanger, the primary closed loop including a first strainer having a first filter and a first flush valve, the first filter configured to collect debris from the first fluid, the first flush valve configured to selectively remove the debris from the first filter; and
a secondary closed loop configured to circulate a second fluid through the heat exchanger, the second fluid configured to be cooled by the first fluid, the secondary closed loop including
a second strainer including a second filter and a second flush valve, the second filter configured to collect debris from the second fluid, the second flush valve configured to selectively remove the debris from the second filter, and
a third strainer including a third filter and a third flush valve, the third filter configured to collect debris from the second fluid, the third flush valve configured to selectively remove the debris from the third filter.

2. The cooling distribution unit of claim 1, wherein the second strainer and the third strainer are positioned in parallel within the secondary closed loop.

3. The cooling distribution unit of claim 1, wherein the second strainer is positioned between a first pair of valves configured to fluidly isolate the second strainer from a rest of the secondary closed loop.

4. The cooling distribution unit of claim 3, wherein the second flush valve is adjustable between an opened position and a closed position, and wherein the second flush valve is configured to be moved to the opened position with the second strainer fluidly isolated from the rest of the secondary closed loop to remove the debris from the second filter.

5. The cooling distribution unit of claim 4, wherein the third strainer is positioned between second a pair of valves configured to fluidly isolate the third strainer from the rest of the secondary closed loop.

6. The cooling distribution unit of claim 5, wherein the third flush valve is adjustable between an opened position and a closed position, and wherein the third flush valve is configured to be moved to the opened position with the third strainer fluidly isolated from the rest of the secondary closed loop to remove the debris from the third filter.

7. The cooling distribution unit of claim 1, wherein each of the first strainer, the second strainer, and the third strainer is a Y-strainer.

8. The cooling distribution unit of claim 1, wherein the first filter is a 500 micron filter, the second filter is a 50 micron filter, and the third filter is a 50 micron filter.

9. The cooling distribution unit of claim 1, wherein the second strainer and the third strainer are identical.

10. The cooling distribution unit of claim 1, wherein the first fluid is water, and wherein the second fluid is a solution including 25% propylene glycol and 75% water.

11. The cooling distribution unit of claim 1, wherein the secondary closed loop is configured to circulate the second fluid across one or more electrical components to pick up heat from the one or more electrical components.

12. The cooling distribution unit of claim 1, wherein the first filter includes a cylindrical wall with a pair of opposite openings.

13. The cooling distribution unit of claim 12, wherein the cylindrical wall is configured to filter the first fluid, and includes pores that allow the first fluid to pass through and inhibit debris from passing through.

14. The cooling distribution unit of claim 1, wherein the first flush valve is one of a butterfly valve, gate valve, or ball valve.

15. The cooling distribution unit of claim 1, wherein the second filter is a micron filter.

16. The cooling distribution unit of claim 2, wherein the second strainer is positioned between a first upstream valve and a first downstream valve, such that the second strainer is fluidly isolated.

17. The cooling distribution unit of claim 16, wherein the third strainer is positioned between a second upstream valve and a second downstream valve, such that the third strainer is fluidly isolated.

18. A cooling distribution unit comprising:
a heat exchanger;
a primary closed loop configured to circulate a first fluid through the heat exchanger; and
a secondary closed loop configured to circulate a second fluid through the heat exchanger, the second fluid configured to be cooled by the first fluid, the secondary closed loop including
a first strainer including a first filter and a first flush valve, the first filter configured to collect debris from the second fluid, the first flush valve configured to selectively remove the debris from the first filter, and
a second strainer including a second filter and a second flush valve, the second filter configured to collect debris from the second fluid, the second flush valve configured to selectively remove the debris from the second filter;
wherein the first strainer and the second strainer are positioned in parallel within the secondary closed loop.

19. The cooling distribution unit of claim 18, wherein the first strainer is positioned between a first upstream valve and a first downstream valve, such that the first strainer is fluidly isolated.

20. The cooling distribution unit of claim 19, wherein the second strainer is positioned between a second upstream valve and a second downstream valve, such that the second strainer is fluidly isolated.
